(19) United States
(12) Patent Application Publication
(10) Pub. No.: US 2026/0047384 A1
(43) Pub. Date: Feb. 12, 2026

(54) CASSETTE SPRING SIZE ADAPTING SYSTEM

(71) Applicant: ENTEGRIS, INC., Billerica, MA (US)

(72) Inventors: Hang Khim Tan, Bukit Mertajam (MY); Mohamad Zakaria Abd Mutholib, Kulim (MY)

(21) Appl. No.: 19/292,831

(22) Filed: Aug. 6, 2025

Related U.S. Application Data
(60) Provisional application No. 63/680,017, filed on Aug. 6, 2024.

(51) Int. Cl. H01L 21/673

(52) U.S. Cl. CPC H01L 21/67369

(57) ABSTRACT

A size adapter for a substrate container includes an engagement feature capable of engaging a cassette spring provided in the substrate container. The size adapter further includes a cassette contact surface. The size adapter can be configured such that the cassette contact surface is positioned within an internal space of the substrate container such that the cassette contact surface can retain a position of a cassette that is of a size smaller than a size the substrate container is configured to accommodate.

### FIELD

This disclosure is directed to substrate containers, particularly adapters for allowing use of different sizes of cassettes within the substrate containers.

### BACKGROUND

Substrate containers can use cassettes to store substrates. The cassettes are typically sized to correspond to the dimensions of the substrate container. Cassette springs can be included in the substrate container to restrict movement of cassettes of the corresponding size in a vertical direction of the substrate container and thus retain the cassettes. However, it may be desirable to use different sized cassettes for some applications, which could not be retained by the cassette springs of the substrate container.

### SUMMARY

This disclosure is directed to substrate containers, particularly adapters for allowing use of different sizes of cassettes within the substrate containers.

By allowing smaller cassettes to have vertical retention while within a substrate container, size adapters and substrate containers including such size adapters can accommodate smaller cassettes with reduced risk of damage to the cassette, container, or substrates during handling of the substrate container. This can also allow larger substrate containers to be used with a variety of cassettes, reducing the need for additional, smaller containers for use with smaller cassettes.

By being attachable to and removable from cassette springs within the substrate container, the use of the size adapters can be simplified, removing a need to remove or replace cassette springs. Attachment to the cassette springs can allow for deflection of the size adapter and/or the cassette spring to cushion the cassette and its contents during a shock event, such as the substrate container being dropped, struck, rapidly accelerated or decelerated and the like.

The size adapters can be shaped and sized to be washable, for example by having features that facilitate drying following a washing process, for example by avoiding the inclusion of closed recesses, by ensuring sufficient distance between parts of various features such as retention features, and the like. This can ensure cleanliness of the size adapters, allowing their use in delicate manufacturing processes sensitive to contamination by water or other chemicals.

In an embodiment, an article includes a size adapter for a substrate container, the size adapter including an engagement feature configured to engage a cassette spring of the substrate container and a cassette contact surface.

In an embodiment, the engagement feature is a snap-fit engagement feature configured to be removable from the cassette spring.

In an embodiment, the size adapter further includes a second engagement feature configured to engage a cassette spring of the substrate container.

In an embodiment, the cassette contact surface is provided between the engagement feature and the second engagement feature.

In an embodiment, the size adapter further includes at least one pillar configured to contact a pod dome when at least one of the cassette spring or the size adapter is deflected by at least a predetermined amount.

In an embodiment, the size adapter does not include any closed recesses.

In an embodiment, the cassette contact surface is a roller attached to the size adapter.

In an embodiment, a substrate container includes a pod door and a pod dome defining an internal space configured to accommodate a first cassette having a first size. The substrate container further includes a plurality of cassette springs provided in the pod dome and one or more size adapters. Each of the one or more size adapters include an engagement feature configured to engage one of the plurality of cassette springs and a cassette contact surface. The cassette contact surface is configured to engage a second cassette, the second cassette having a second size, the second size smaller than the first, when the one or more size adapters are engaged with the respective cassette springs and the second cassette is provided in the internal space.

In an embodiment, the substrate container further includes a base, the base configured to be placed upon the pod door, the base configured to support the second cassette.

In an embodiment, the engagement feature is a snap-fit engagement feature configured to be removable from the respective cassette spring.

In an embodiment, the size adapter further includes a second engagement feature configured to engage another cassette spring of the substrate container. In an embodiment, the cassette contact surface is provided between the engagement feature and the second engagement feature.

In an embodiment, the size adapter further includes at least one pillar configured to contact a pod dome when at least one of the cassette spring or the size adapter is deflected by at least a predetermined amount. In an embodiment, the substrate container further includes a base, the base configured to be placed upon the pod door, the base configured to support the second cassette, the base including a guide. In an embodiment, a height of the guide is greater than a distance between the pillar and an opposing surface of the pod dome when the second cassette is within the internal space and the pod dome is joined to the pod door.

In an embodiment, the one or more size adapters are each configured to interfere with the second cassette such that the one or more size adapters apply a pre-tension force on the second cassette when the second cassette is within the internal space and the pod dome is joined to the pod door.

In an embodiment, each of the one or more size adapters do not include any closed recesses.

In an embodiment, the cassette contact surface of at least one of the one or more size adapters is a roller attached to said size adapter.

### DRAWINGS

FIG. 1A shows a substrate container according to an embodiment.

FIG. 1B shows a substrate container according to an embodiment.

FIG. 2A shows size adapters and cassette springs according to an embodiment.

FIG. 2B shows size adapters attached to cassette springs according to an embodiment.

FIG. 3A shows a size adapter and cassette springs according to an embodiment.

FIG. 3B shows a size adapter attached to cassette springs according to an embodiment.

FIG. 4A shows a roller assembly of a size adapter according to an embodiment.

FIG. 4B shows a roller assembly of a size adapter according to an embodiment.

### DETAILED DESCRIPTION

This disclosure is directed to substrate containers, particularly adapters for allowing use of different sizes of cassettes within the substrate containers.

As used herein, “deflected” refers to a solid object being moved from a resting position when force is applied, for example by flexing, bending, or the like. The object experiencing deflection can return to the resting position when the force is removed. In embodiments, there may be some drift in the resting position due to repeated or long-term deflection.

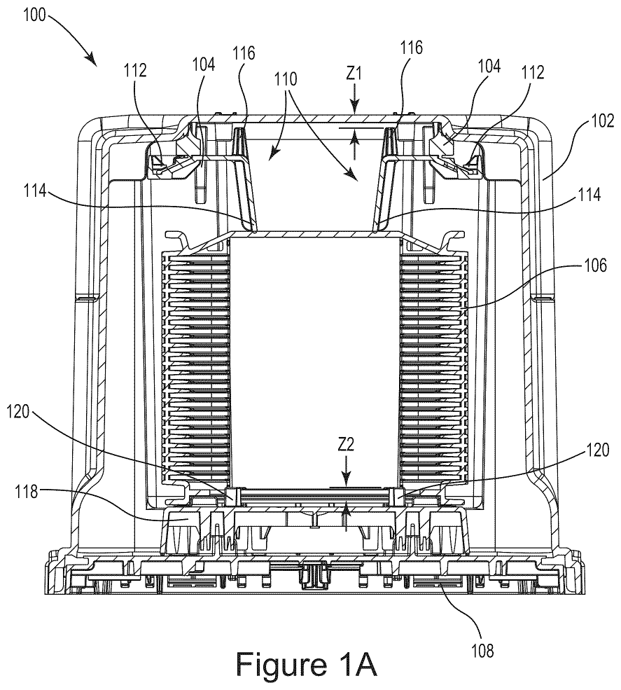

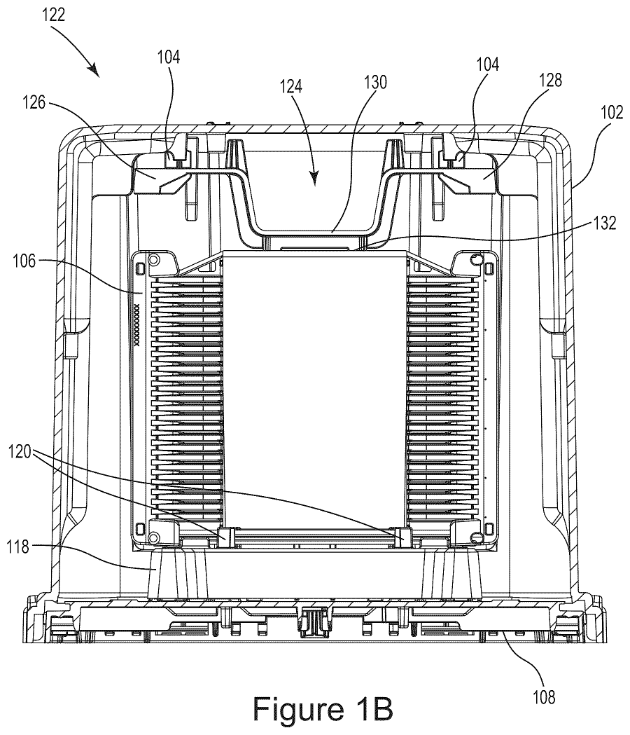

FIG. 1A shows a substrate container according to an embodiment. Substrate container 100 includes pod dome 102, cassette springs 104, cassette 106, and pod door 108. Size adapters 110 are provided in substrate container 110. The size adapters 110 include a cassette spring engagement feature 112, a cassette contact surface 114, and a pillar 116. A base 118 can optionally be included in the substrate container 100.

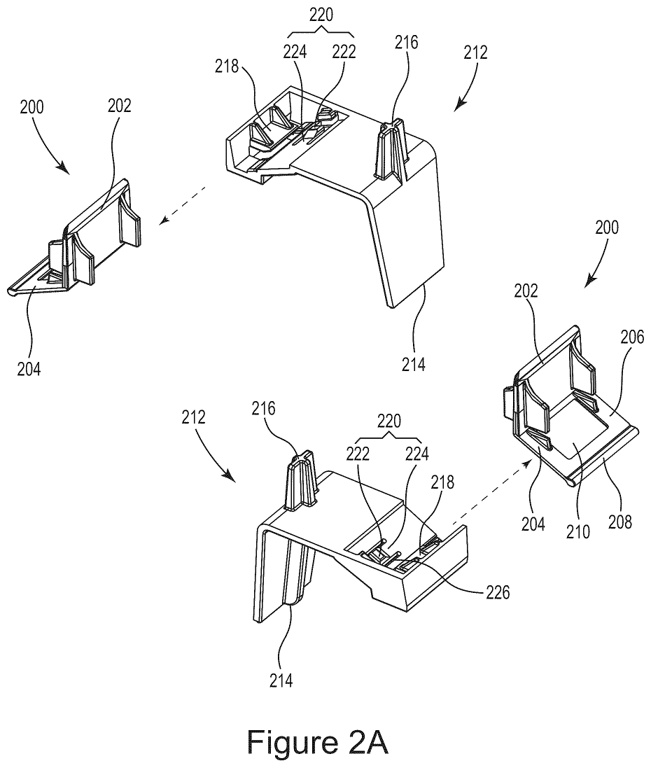

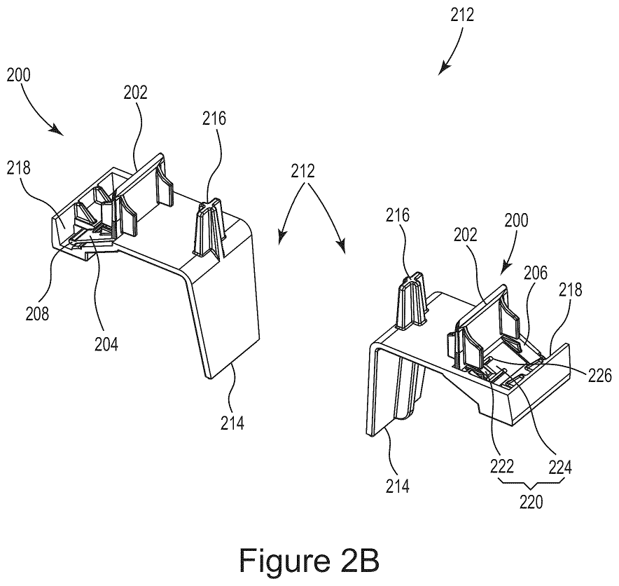

Substrate container 100 is a container configured to accommodate a cassette, with substrates being stored in the cassette 106. The substrate container 100 can be, as a non-limiting example, a standard mechanical interface (SMIF) pod. Substrate container 100 can be a bottom-opening container, where an opening of pod dome 102 configured to receive pod door 108 is provided on a bottom of the substrate container 100, and the pod dome 102 can be placed over the cassette 106 and pod door 108 to enclose the container. Substrate container 100 can be configured to accommodate a cassette having a larger size than a size of the cassette 106 shown in FIGS. 1 and 2. As a non-limiting example, where cassette 106 is a 6-inch size cassette, the substrate container 100 can include an internal space configured to accommodate an 8-inch size cassette.

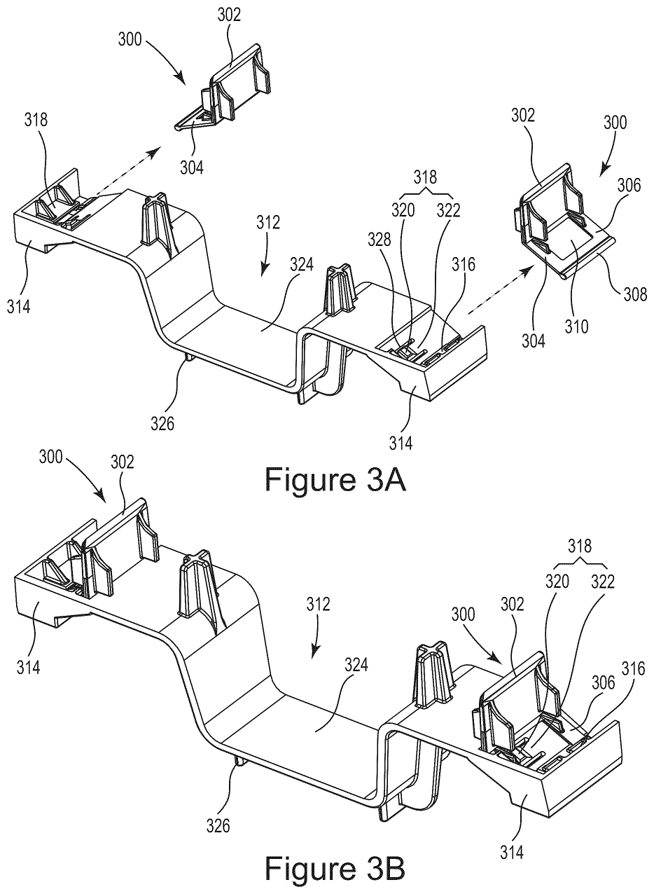

Pod dome 102 includes side walls and a top wall defining an internal space and an open end at a bottom of pod dome 102. The open end is configured to be enclosed by joining pod dome 102 to pod door 108. The internal space defined by pod dome 102 is configured to accommodate a cassette having at least one dimension greater than a corresponding dimension of cassette 106 shown in FIGS. 1A and 1B. Cassette springs 104 can be provided on an internal surface of pod dome 102. Cassette springs 104 are configured to contact a cassette that the pod dome 102 is configured to accommodate, so as to restrict movement of the cassette when said cassette is within substrate container 100 and the pod dome 102 and pod door 108 are secured to one another, for example by a latch provided on pod door 108. Non-limiting examples of cassette springs 104 are described below and shown in FIGS. 2A, 2B, 3A, and 3B.

Cassette 106 is a cassette configured to accommodate one or more substrates, such as wafers. The cassette 106 has a size that is smaller than a size that substrate container 100 is configured to accommodate during ordinary use. The cassette 106 can be, as a non-limiting example, a 6 inch size cassette when the substrate container 100 is configured to accommodate an 8 inch size cassette. The cassette can include a horizontal bar configured to interface with cassette guides 120 provided on a pod door 108 or on an optional base 118. The cassette 106 can include substrate supports defining one or more slots configured to receive the substrates.

Pod door 108 is configured to enclose the open end of pod door 102. Pod door 108 can include a latch configured to secure the pod door 108 to pod dome 102. Pod door 108 can include cassette guides such as the cassette guides 120 shown on the base 118, configured to align and/or retain a cassette that the substrate container 100 is configured to accommodate.

Size adapters 110 each attach to one of the cassette springs 104. Each size adapter 110 includes a cassette spring engagement feature 112 configured to engage with the corresponding cassette spring so as to retain size adapter 110 within the internal space of the substrate container 100. The cassette spring engagement features 112 of the size adapters 110 are configured to allow removal of the size adapters from the substrate container 100. Size adapters 110 can be used when cassette 106 is to be used in the substrate container 100, the substrate container 100 being sized to accommodate a cassette larger than the cassette 100.

Cassette contact surface 114 is provided on an extension from the body of the size adapter 110. Cassette contact surface 114 is configured to contact the cassette 106 when the substrate container 100 is closed with the cassette 106 contained within and the size adapters 110 attached to the cassette springs 104. The size adapter 110 can be configured such that when the substrate container 100 is closed with the cassette 106 contained within and the size adapters 110 attached to the cassette springs 104, interference between the cassette 106 and the cassette contact surface deflects at least a portion of one or both of the size adapter 110 and the cassette spring 104, such that the cassette contact surface 114 applies a spring force to the cassette 106. The spring force can retain a position of the cassette 106, resisting movement of the cassette 106 relative to pod dome 102 and/or pod door 108 when the substrate container experiences acceleration or deceleration.

Pillar 116 can extend vertically from the body of the size adapter 110, at an end of the body from which the portion of size adapter 110 including cassette contact surface 114 extends. Pillar 116 can be configured to contact the pod dome 102 when the size adapter 110 is deflected to a certain extent. The size adapter 110 can be configured such that pillar 116 contacts the pod dome during a shock event, such as the substrate container 100 being dropped, struck, or otherwise subjected to rapid acceleration or deceleration, so as to restrict movement of the cassette 106 within the internal space of the substrate container 100.

Base 118 can be provided to support cassette 106 on pod door 108 in an embodiment. Base 118 can have a height selected to provide the cassette 106 at a height for interfacing with the size adapters 110. The height of base 118 can be based on the size of the cassette 106 and/or the size of cassette the pod dome 102 is configured to accommodate. Base 118 can include cassette guides 120 extending vertically from the base 118. The cassette guides 120 can be configured to align the cassette 106 on the base 118, for example by defining a channel configured to receive a horizontal bar extending across a bottom of the cassette 106. The cassette guides can have a height z2 that is greater than a distance z1 between the ends of the pillars 116 and an opposing internal surface of the pod dome 102 when the size adapters contact 110 contact the cassette 106 while the pod dome 102 is joined to the pod door 108. The height z2 being greater than the distance z1 can prevent the cassette 106 from escaping the cassette guides 120 during a shock event such as the container 100 being dropped, struck, or otherwise subjected to rapid acceleration or deceleration.

FIG. 1B shows a substrate container according to an embodiment. Substrate container 122 includes pod dome 102, cassette springs 104, cassette 106, and pod door 108 as described above and shown in FIG. 1A. Additionally, substrate container 122 can optionally include base 118 as described above and shown in FIG. 1A. Substrate container 122 includes size adapter 124. Size adapter 124 includes first cassette spring engagement feature 126 and second cassette spring engagement feature 128. Size adapter 124 includes cassette retention arm 130 and cassette contact surface 132.

Size adapter 124 is a size adapter configured to engage with a plurality of the cassette springs 104. The size adapter 124 includes a first cassette spring engagement feature 126 at a first end of the size adapter 124 and a second cassette spring engagement feature 128 at a second end of the size adapter 124. Each of the first and second cassette spring engagement features 126, 128 can each be configured to engage with the respective cassette spring 104 so as to retain the size adapter 124 within the internal space of substrate container 122. The first and second cassette spring engagement features 126, 128 can each be configured to be removable from the respective cassette spring 104, for example to allow removal of size adapter 124 for cleaning, to allow substrate container 122 to be used with cassettes of a different size, or any other suitable reason for removal.

Cassette retention arm 130 extends between first and second cassette spring engagement features 124, 126. Cassette contact surface 132 can be provided on cassette retention arm 130 or on a projection therefrom. The cassette contact surface 132 is configured to contact the cassette 106 so as to retain a vertical position of the cassette 106 within the substrate container 100 and the pod dome 102 is secured to the pod door 108.

FIG. 2A shows size adapters and cassette springs according to an embodiment. Cassette springs 200 each include a pod dome attachment segment 202 and a spring region 204 including a frame 206 and a cassette contact surface 208. The frame 206 defines and opening 210. Size adapters 212 each include a cassette contact surface 214, a column 216, a channel 218, and a snap-fit feature 220 including latching tab 222 and deflectable arm 224.

Cassette spring 200 is a cassette spring configured to be attached to a pod dome, such as the pod dome 102 described above and shown in FIGS. 1A and 1B. Cassette spring 200 includes a pod dome attachment segment 202 configured to engage with the pod dome, for example through any suitable mechanical engagement, to retain the cassette spring within the internal space of a substrate container including the pod dome.

Spring region 204 is configured to provide cassette contact surface 208 where the cassette contact surface can contact a cassette of a suitable size for the substrate container. The spring region 204 can be configured to allow deflection, such that the cassette contact surface 208 can provide spring force against a surface of the cassette, so as to retain a position of the cassette within the substrate container. The spring region 204 can include a frame 206. Frame 206 can include beams, at least one of the beams including cassette contact surface 208. The beams of frame 206 can be capable of deflection when cassette contact surface 208 contacts the cassette, thereby applying spring force for the cassette contact surface 208 to transfer to the cassette. Opening 210 is defined by the beams of frame 206 and the body of the cassette spring 200. The beams of frame 206 can be sized and materials can be selected to as to provide the desired spring force to retain a cassette using the cassette spring 200. The shape and size of the cassette contact surface 208 can be configured to engage the cassette at a suitable region thereof, such as a top wall of the cassette, away from a handle or any other functional features.

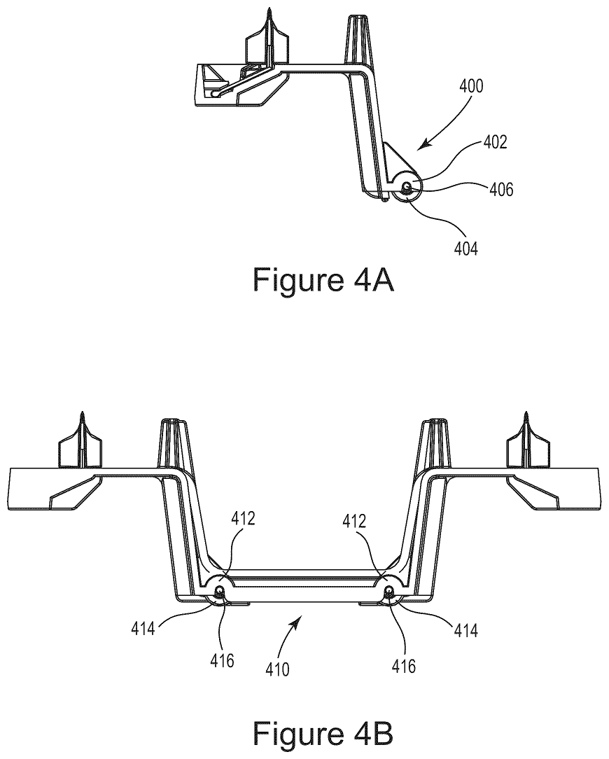

Size adapters 212 can be attached to respective cassette springs 200 so as to allow the substrate container to secure a cassette smaller than a standard cassette size for the substrate container in the internal space thereof. The size adapters 212 each include a cassette contact surface 214 configured to contact the cassette so as to retain the cassette within the substrate container. The cassette contact surface 214 can be provided on a portion of the size adapter 212 extending in a direction having a vertical component extending downwards with respect to the substrate container including the cassette spring 200. The size adapters 212 can each be configured to provide the cassette contact surface at a position to contact the cassette when the cassette is placed within the substrate container and the container is closed, optionally along with a base such as the base 118 described above and shown in FIGS. 1A and 1B. The size adapters 212 can be configured to interfere with the cassette when the pod dome is attached to the pod door with the cassette contained therein, thus causing at least some deflection of the cassette spring 200 and/or the size adapter 212, thereby providing pre-tensioning and applying a retention force to the cassette. In an embodiment, the cassette contact surface 214 can be provided on one or more rollers, for example as shown in FIG. 4A and described below.

The body of size adapter 212 can optionally include any suitable openings and have any suitable shape to facilitate drying, avoiding or reducing the retention of moisture in the size adapter 212. An example of such optional structure for the body of size adapter 212 can include providing openings such that there are no enclosed recesses or other regions that can retain water. As used herein, an enclosed recess is a recess having only one point of entry or exit through which fluid can pass. Regions having openings on at least two different sides thereof, such as through holes, channels having an opening provided on a side thereof, and the like are examples of recesses that are not enclosed recesses as defined herein. An enclosed recess could be, for example, a channel having one opening and closed at an opposing end with no venting provided along the channel, a drilled hole that does not completely penetrate the body, and the like.

Column 216 can be provided extending opposite the cassette contact surface 214 with respect to the vertical direction of the substrate container. Column 216 can be configured to contact the pod dome when the cassette spring 200 and/or the size adapter 212 are deflected to a certain extent. Column 216 can be sized such that column 216 prevents the cassette from escaping a cassette guide provided on a pod door or a base provided on the pod door, for example by being configured to restrict movement of the cassette beyond a height that is smaller than a height of the cassette guide, for example as shown in FIG. 1A and described above.

Channel 218 is configured to receive at least a portion of the frame 206 of the cassette spring 200. The channel 218 can be configured such that deflection of the cassette spring 200 can change a position of the size adapter 212, for example to allow movement of the cassette contact surface 214 and the column 216 in a direction including a vertical component relative to the substrate container. In an embodiment, the channel 218 can extend at least a length of the frame 206 of the cassette spring 200.

A snap-fit feature 220 can be positioned to engage the cassette spring 200, when the frame 206 of the cassette spring is received in the channel 218. The snap-fit feature 220 can retain the channel 218 and the frame 206 relative to one another, such that the size adapter 212 is secured to the cassette spring 200. The snap-fit feature 220 can prevent the size adapter 212 from being slid off of the cassette spring 200. The snap-fit feature 220 can be manipulated, for example by an automated tool or manually by a user, to allow the separation of the size adapter 212 from the cassette spring 200, for example for cleaning of the size adapter 212, use of the container with another cassette, or the like.

Latching tab 222 is configured to engage an inner perimeter of the frame 206 when the cassette spring 200 is engaged by snap-fit feature 220. The latching tab 222 can be a projection extending from deflectable arm 224. The latching tab 222 can include a latching surface configured to engage with at least a portion of the frame 206 so as to prevent the frame 206 from being withdrawn from the channel 218. The latching tab 222 can include a ramped surface, such that the latching tab 222 can drive deflection of the deflectable arm 224 to allow the frame 206 to pass over the latching tab 222 when inserting the frame 206 into the channel 218. The latching tab 222 can prevent the movement of the size adapter 212 such that the frame 206 separates from the channel 218. Latching tab 222 can be provided on a deflectable arm 224. The deflectable arm 224 can extend into an opening 226 provided in the size adapter 212. The deflectable arm 224 can be deflected to allow movement of the latching tab, for example to allow the ramped surface to pass over the frame 206 when attaching the size adapter 212 to the cassette spring 200, or to allow the latching tab 222 to be moved by an automated tool or a manual user to allow removal of the size adapter 212 from the cassette spring 200.

The opening 226, deflectable arm 224, and/or latching tab 222 can be respectively sized to provide a space between the snap-fit feature 220 and the body of size adapter 212 configured to allow water to flow freely through the space. This can reduce or prevent the trapping of water within channel 218 or within the gap between opening 226 and the snap-fit feature 220.

FIG. 2B shows size adapters attached to cassette springs according to an embodiment. When the size adapters 212 and the cassette springs 200 are attached, the snap-fit feature 220 presents latching tab 222 such that one side of frame 306 is retained within the channel 218, thereby mechanically attaching the size adapter 212 to the respective cassette spring 200. The size adapter 212 can be removed from the corresponding cassette spring 200 by deflecting the deflectable arm 224 such that latching tab 222 does not obstruct the removal of the portion of frame 206 from channel 218, allowing the size adapter 212 to be removed from the cassette spring 200. The size adapter 212 can be removed when the container including cassette spring 200 is to be used with a different size of cassette, when size adapter 212 is to be cleaned, or the like.

FIG. 3A shows a size adapter and cassette springs according to an embodiment. Cassette springs 300 each include a pod dome attachment segment 302 and a spring region 304 including a frame 306 and a cassette contact surface 308. The frame 306 defines an opening 310. Size adapter 312 includes cassette spring engagement features 314 each including a channel 316 and a snap-fit feature 318. Snap-fit feature 318 includes latching tab 320 and deflectable arm 322. The size adapter 312 includes cassette retention arm 324 extending between the cassette spring engagement features 314. A cassette contact surface 326 can be provided on cassette retention arm 324.

Cassette springs 300 each are a cassette spring configured to be attached to a pod dome, such as the pod dome 102 described above and shown in FIGS. 1A and 1B. Cassette springs 300 each include a pod dome attachment segment 302 configured to engage with the pod dome, for example through any suitable mechanical engagement, to retain the cassette spring within the internal space of a substrate container including the pod dome.

In each of the cassette springs 300, spring region 304 is configured to provide cassette contact surface 308 where the cassette contact surface can contact a cassette of a suitable size for the substrate container. The spring region 304 can be configured to allow deflection, such that the cassette contact surface 308 can provide spring force against a surface of the cassette, so as to retain a position of the cassette within the substrate container. The spring region 304 can include a frame 306. Frame 306 can include beams, at least one of the beams including cassette contact surface 308. The beams of frame 306 can be capable of deflection when cassette contact surface 308 contacts the cassette, thereby applying spring force for the cassette contact surface 308 to transfer to the cassette. Opening 310 is defined by the beams of frame 306 and the body of the cassette spring 300. The beams of frame 306 can be sized and materials can be selected to as to provide the desired spring force to retain a cassette using the cassette spring 300. The shape and size of the cassette contact surface 308 can be configured to engage the cassette at a suitable region thereof, such as a top wall of the cassette, away from a handle or any other functional features.

Size adapter 312 is configured to interface with a plurality of cassette springs 300 within the substrate container. When installed into a substrate container, size adapter 312 can allow a cassette smaller than a standard size for the substrate container to be retained within the substrate container. The size adapter 312 includes at least two cassette spring engagement features 314. In the embodiment shown in FIGS. 3A and 3B, the cassette spring engagement features 314 are provided on opposite sides of the size adapter 312.

The body of size adapter 312 can optionally include any suitable openings and have any suitable shape to facilitate drying, avoiding or reducing the retention of moisture in the size adapter 312. An example of such optional structure for the body of size adapter 312 can include providing openings such that there are no enclosed recesses or other regions that can retain water. As used herein, an enclosed recess is a recess having only one point of entry or exit through which fluid can pass. Regions having openings on at least two different sides thereof, such as through holes, channels having an opening provided on a side thereof, and the like are examples of recesses that are not enclosed recesses as defined herein. An enclosed recess could be, for example, a channel having one opening and closed at an opposing end with no venting provided along the channel, a drilled hole that does not completely penetrate the body, and the like.

Each of the cassette spring engagement features 314 includes a channel 316 and a snap-fit feature 318. Channel 316 is configured to receive at least a portion of the frame 306 of the cassette spring 300. In an embodiment, the channel 316 can extend at least a length of the frame 306 of the cassette spring 300. Each of the cassette spring engagement features 314 can be positioned on size adapter 312 such that each cassette spring engagement feature 314 engages the respective cassette spring 300 at the same time.

Snap-fit feature 318 can be positioned to engage the cassette spring 300, when the frame 306 of the cassette spring is received in the channel 316. The snap-fit feature 318 can retain the channel 316 and the frame 306 relative to one another, such that the size adapter 312 is secured to the cassette spring 300. The snap-fit feature 318 can prevent the size adapter 312 from being slid off of the cassette spring 300. The snap-fit feature 318 can be manipulated, for example by an automated tool or manually by a user, to allow the separation of the size adapter 312 from the cassette spring 300, for example for cleaning of the size adapter 312, use of the container with another cassette, or the like.

Latching tab 320 is configured to engage an inner perimeter of the frame 306 when the cassette spring 300 is engaged by snap-fit feature 318. The latching tab 320 can be a projection extending from deflectable arm 322. The latching tab 320 can include a latching surface configured to engage with at least a portion of the frame 306 so as to prevent the frame 306 from being withdrawn from the channel 316. The latching tab 320 can include a ramped surface, such that the latching tab 320 can drive deflection of the deflectable arm 322 to allow the frame 306 to pass over the latching tab 320 when inserting the frame 306 into the channel 316. The latching tab 320 can prevent the movement of the size adapter 312 such that the frame 306 separates from the channel 316. Latching tab 320 can be provided on a deflectable arm 322. The deflectable arm 322 can extend into an opening 328 provided in the size adapter 312. The deflectable arm 322 can be deflected to allow movement of the latching tab, for example to allow the ramped surface to pass over the frame 306 when attaching the size adapter 312 to the cassette spring 300, or to allow the latching tab 320 to be moved by an automated tool or a manual user to allow removal of the size adapter 312 from the cassette spring 300.

The opening 328, deflectable arm 322, and/or latching tab 320 can be respectively sized to provide a space between the snap-fit feature 318 and the body of size adapter 312 configured to allow water to flow freely through the space. This can reduce or prevent the trapping of water within channel 318 or within the gap between opening 328 and the snap-fit feature 318.

Cassette retention arm 324 extends from one of the cassette spring engagement features 314 to at least one other cassette spring engagement feature 314. In the embodiment shown in FIGS. 3A and 3B, the cassette retention arm 324 extends linearly between the two cassette spring engagement features 314. It is understood that cassette retention arm 324 can include one or more curves, one or more offset portions, one or more changes of direction, or the like. In an embodiment, the cassette retention arm 324 is rigid, such that the cassette retention arm 324 does not deflect as a result of contact with the cassette. In an embodiment, at least a portion of the cassette retention arm 324 can deflect as a result of contact with the cassette, for example to provide spring force to retain the cassette, to absorb some shock to the substrate container and the cassette, or the like. A cassette contact surface 326 is provided on the cassette retention arm or on a feature extending therefrom. The cassette contact surface 326 is configured to be in contact with or be positioned in near the cassette when the size adapter 312 is attached to the cassette springs 300 and the substrate container is closed with the cassette and optionally a base contained therein. In an embodiment, the cassette contact surface 326 contacts the cassette at rest within the substrate container. In an embodiment, the cassette contact surface 326 is provided in a position that does not directly contact the cassette at rest, but is spaced such that the cassette would contact the cassette contact surface 326 prior to escaping from other retention or alignment features contacting the cassette such as the cassette guides 120 as described above and shown in FIG. 1. In an embodiment, the cassette contact surface 326 can be presented on a roller, for example as shown in FIG. 4B and described below.

FIG. 3B shows a size adapter attached to cassette springs according to an embodiment. When the size adapter 312 is attached to the cassette springs 300, the snap-fit features 318 each present latching tab 320 such that one side of the respective frame 306 is retained within the respective channel 316, thereby mechanically attaching the size adapter 312 to the respective cassette spring 300. The size adapter 312 can be removed from the cassette springs 300 by deflecting each of the deflectable arms 322 such that latching tabs 320 does not obstruct the removal of the respective portions of frames 306 from the respective channels 316, allowing the size adapter 312 to be removed from the cassette springs 300. The size adapter 312 can be removed when the container including cassette springs 300 is to be used with a different size of cassette, when the size adapter 312 is to be cleaned, or the like.

FIG. 4A shows a roller assembly of a size adapter according to an embodiment. Roller assembly 400 can be used as a cassette contact surface of a size adapter, such as the size adapters 100 and 200 described above and shown in FIGS. 1A, 2A, and 2B. Roller assembly 400 can be positioned at an end of a projection where the cassette contact surface is to be provided, for example at the position of cassette contact surface 214 of the size adapter 200 described above and shown in FIGS. 2A and 2B. Each of the clips 402 can receive an axle 406 such that the roller 404 can rotate about the axle 406. In an embodiment, the axle 406 can be attached to or formed integrally with the respective roller 404. In an embodiment, the axle 406 can be a separate element configured to extend through an aperture formed in the roller 404. The roller 404 can be attached to the clip 402 such that the roller 404 can rotate in response to movement of a contacted cassette relative to the size adapter including roller assembly 400. The roller 404 can be configured to extend further towards the cassette than any other portion of the roller assembly 400, such that the only contact with the cassette is made at a surface provided on the roller 404. The rotation of roller 404 can allow the relative movement of the cassette to the size adapter to occur with less friction compared to contact with a fixed surface, thereby reducing particle generation and risk of contamination within the substrate container should the cassette experience movement relative to the size adapter including roller assembly 400.

FIG. 4B shows a roller assembly of a size adapter according to an embodiment. Roller assembly 410 can be provided on a size adapter such as size adapters 124 or 300 as shown in FIGS. 1B, 3A, and 3B and described above. Roller assembly 410 can be provided along a cassette retention arm of the size adapter, such as the cassette retention arm 324 as described above and shown in FIGS. 3A and 3B. The roller assembly 410 can include one or more clips 412 and one or more rollers 414 rotatably mounted to the clips 412. Each of the clips 412 can receive an axle 416 such that the roller 414 can rotate about the axle 416. In an embodiment, the axle 416 can be attached to or formed integrally with the respective roller 414. In an embodiment, the axle 416 can be a separate element configured to extend through an aperture formed in the roller 414. The rollers 414 can be attached to the respective clips 412 such that the rollers 414 can each rotate in response to movement of a contacted cassette relative to the size adapter including roller assembly 410. The rotation of the rollers 414 can be independent of one another, that is one roller 414 can rotate without another roller 414 necessarily rotating to a same extent. The rollers 414 can be configured to extend further towards the cassette than any other portion of the roller assembly 410, such that the only contact with the cassette is made at a surface provided on one or more of the rollers 414. The rotation of rollers 414 can allow the relative movement of the cassette to the size adapter to occur with less friction compared to contact with a fixed surface, thereby reducing particle generation and risk of contamination within the substrate container should the cassette experience movement relative to the size adapter including roller assembly 400.

### Aspects

It is understood that any of aspects 1-7 can be combined with any of aspects 9-18.

Aspect 1. An article, comprising a size adapter for a substrate container, the size adapter including an engagement feature configured to engage a cassette spring of the substrate container and a cassette contact surface.

Aspect 2. The article according to aspect 1, wherein the engagement feature is a snap-fit engagement feature configured to be removable from the cassette spring.

Aspect 3. The article according to any of aspects 1-2, wherein the size adapter further includes a second engagement feature configured to engage a cassette spring of the substrate container.

Aspect 4. The article according to aspect 3, wherein the cassette contact surface is provided between the engagement feature and the second engagement feature.

Aspect 5. The article according to any of aspects 1-4, wherein the size adapter further includes at least one pillar configured to contact a pod dome when at least one of the cassette spring or the size adapter are deflected by at least a predetermined amount.

Aspect 6. The article according to any of aspects 1-5, wherein the size adapter does not include any closed recesses.

Aspect 7. The article according to any of aspects 1-6, wherein the cassette contact surface is a roller attached to the size adapter.

Aspect 8. A substrate container, comprising:
a pod door;
a pod dome, the pod dome defining an internal space configured to accommodate a first cassette having a first size;
a plurality of cassette springs provided in the pod dome; and
one or more size adapters, each of the one or more size adapters including an engagement feature configured to engage one of the plurality of cassette springs and a cassette contact surface, the cassette contact surface configured to engage a second cassette, the second cassette having a second size, the second size smaller than the first, when the one or more size adapters are engaged with the respective cassette springs and the second cassette is provided in the internal space.

Aspect 9. The substrate container according to aspect 8, further comprising a base, the base configured to be placed upon the pod door, the base configured to support the second cassette.

Aspect 10. The substrate container according to any of aspects 8-9, wherein the engagement feature is a snap-fit engagement feature configured to be removable from the respective cassette spring.

Aspect 11. The substrate container according to any of aspects 8-10, wherein the size adapter further includes a second engagement feature configured to engage another cassette spring of the substrate container.

Aspect 12. The substrate container according to aspect 11, wherein the cassette contact surface is provided between the engagement feature and the second engagement feature.

Aspect 13. The substrate container according to any of aspects 8-12, wherein the size adapter further includes at least one pillar configured to contact a pod dome when at least one of the cassette spring or the size adapter are deflected by at least a predetermined amount.

Aspect 14. The substrate container according to aspect 13, further comprising a base, the base configured to be placed upon the pod door, the base configured to support the second cassette, the base including a guide.

Aspect 15. The substrate container according to aspect 14, wherein a height of the guide is greater than a distance between the pillar and an opposing surface of the pod dome when the second cassette is within the internal space and the pod dome is joined to the pod door.

Aspect 16. The substrate container according to any of aspects 8-15, wherein the one or more size adapters are each configured to interfere with the second cassette such that the one or more size adapters apply a pre-tension force on the second cassette when the second cassette is within the internal space and the pod dome is joined to the pod door.

Aspect 17. The substrate container according to any of aspects 8-16, wherein each of the one or more size adapters do not include any closed recesses.

Aspect 18. The substrate container according to any of aspects 8-17, wherein the cassette contact surface of at least one of the one or more size adapters is a roller attached to said size adapter.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. An article, comprising a size adapter for a substrate container, the size adapter including an engagement feature configured to engage a cassette spring of the substrate container and a cassette contact surface.

2. The article of claim 1, wherein the engagement feature is a snap-fit engagement feature configured to be removable from the cassette spring.

3. The article of claim 1, wherein the size adapter further includes a second engagement feature configured to engage a cassette spring of the substrate container.

4. The article of claim 3, wherein the cassette contact surface is provided between the engagement feature and the second engagement feature.

5. The article of claim 1, wherein the size adapter further includes at least one pillar configured to contact a pod dome when at least one of the cassette spring or the size adapter are deflected by at least a predetermined amount.

6. The article of claim 1, wherein the size adapter does not include any closed recesses.

7. The article of claim 1, wherein the cassette contact surface is a roller attached to the size adapter.

8. A substrate container, comprising:
a pod door;
a pod dome, the pod dome defining an internal space configured to accommodate a first cassette having a first size;
a plurality of cassette springs provided in the pod dome; and
one or more size adapters, each of the one or more size adapters including an engagement feature configured to engage one of the plurality of cassette springs and a cassette contact surface, the cassette contact surface configured to engage a second cassette, the second cassette having a second size, the second size smaller than the first, when the one or more size adapters are engaged with the respective cassette springs and the second cassette is provided in the internal space.

9. The substrate container of claim 8, further comprising a base, the base configured to be placed upon the pod door, the base configured to support the second cassette.

10. The substrate container of claim 8, wherein the engagement feature is a snap-fit engagement feature configured to be removable from the respective cassette spring.

11. The substrate container of claim 8, wherein the size adapter further includes a second engagement feature configured to engage another cassette spring of the substrate container.

12. The substrate container of claim 11, wherein the cassette contact surface is provided between the engagement feature and the second engagement feature.

13. The substrate container of claim 8, wherein the size adapter further includes at least one pillar configured to contact a pod dome when at least one of the cassette spring or the size adapter are deflected by at least a predetermined amount.

14. The substrate container of claim 13, further comprising a base, the base configured to be placed upon the pod door, the base configured to support the second cassette, the base including a guide.

15. The substrate container of claim 14, wherein a height of the guide is greater than a distance between the pillar and an opposing surface of the pod dome when the second cassette is within the internal space and the pod dome is joined to the pod door.

16. The substrate container of claim 8, wherein the one or more size adapters are each configured to interfere with the second cassette such that the one or more size adapters apply a pre-tension force on the second cassette when the second cassette is within the internal space and the pod dome is joined to the pod door.

17. The substrate container of claim 8, wherein each of the one or more size adapters do not include any closed recesses.

18. The substrate container of claim 8, wherein the cassette contact surface of at least one of the one or more size adapters is a roller attached to said size adapter.
